(19) United States
(12) Patent Application Publication
(10) Pub. No.: US 2011/0048492 A1
(43) Pub. Date: Mar. 3, 2011

(54) SOLAR CELL AND SOLAR CELL MODULE

(75) Inventor: Takeshi NISHIWAKI, Kobe City (JP)

(73) Assignee: SANYO ELECTRIC CO., LTD., Moriguchi City (JP)

(21) Appl. No.: 12/870,896

(22) Filed: Aug. 30, 2010

(30) Foreign Application Priority Data
Aug. 31, 2009 (JP) 2009-200687

(51) Int. Cl. H01L 31/042; H01L 31/04; H01L 31/18

(52) U.S. Cl. 136/244; 136/255; 156/60

(57) ABSTRACT

A solar cell includes: an photoelectric conversion body including a first main surface and a second main surface opposed to the first main surface; a first electrode provided on the first main surface; a second electrode provided on the second main surface; a first conductive connection member connected with the first electrode for connecting the solar cell and another solar cell, wherein the first conductive connection member includes a conductive soft layer at an area facing the first electrode, and the first electrode includes a conductive soft layer at an area facing the first conductive connection member; and a first resin adhesive bonding the first conductive connection member to the first electrode in such a manner that the conductive soft layer of the first electrode and the conductive soft layer of the first conductive connection member abut on each other.

### CROSS REFERENCE TO RELATED APPLICATIONS

This application of the invention titled “Solar Cell and Solar Cell Module” is based upon and claims the benefit of priority under 35 USC 119 from prior Japanese Patent Application No. 2009-200687, filed on Aug. 31, 2009; the entire contents of which are incorporated herein by reference.

### BACKGROUND OF THE INVENTION

1. Field of the Invention

The invention relates to a solar cell and a solar cell module.

2. Description of Related Art

A solar cell system having solar cells is expected to be a new energy conversion system that converts light from the sun into electricity. In recent years, active use of solar cell systems has been increasing as a general household power supply and a large-scale power generation plant.

Currently, under the situation described above, research and development for cost reduction of solar cell systems are actively in progress in order to further spread their use.

FIG. 14A is a perspective view of a solar cell in a solar cell module according to a related art, FIG. 14B is a sectional view of the solar cell, FIG. 15 is a sectional view of a part of the solar cell module, illustrating the connection between the solar cells.

As shown in FIGS. 14A and 14B, solar cell 100 includes semiconductor substrate 101 having a PN junction. Provided on the front surface of semiconductor substrate 101 are: antireflective film 102; and front electrode 103 composed of finger collecting electrodes 103a and bus bar electrodes 103b. Provided on the rear surface of semiconductor substrate 101 is: rear electrode 104 composed of metal-film collecting electrode 104a and bus bar electrodes 104b.

As shown in FIG. 15, in the solar cell module, bus bar electrodes 103b of front electrode 103 of one of adjacent solar cells 100 are connected to bus bar electrodes 104b of rear electrode 104 of the other of the adjacent solar cells 100 with conductive connection member 105 covered with a solder, so that plural solar cells 100 are electrically connected in series or parallel.

The electrically-connected plural solar cells are provided in a filling material filled between an unillustrated front cover made of a light transmissive member and an unillustrated rear cover with a frame supporting the outer edges of the front cover and the rear cover.

In the related art, conductive connection member 105 is generally connected to front electrodes 103 or rear electrodes 104 by melting and solidification of the solder of conductive connection member 105. In such a connecting process wherein the solder is melted with heat, a difference in the thermal expansion coefficients between semiconductor substrate 101 of solar cell 100 and conductive connection member 105 generates stress in solar cell 100. This may cause a crack in the solar cell (the substrate) and lower the yield of the solar cell.

Meanwhile, as a connecting method for connecting conductive connection member 105 to front electrode 103 of solar cell 100 or rear electrode 104 of solar cell 100, there has been suggested a connecting method using a solder and a resin adhesive or a connecting method using a conductive resin adhesive (for example, see Japanese Patent Application Laid-Open No. S58-71667).

Such connecting methods using the resin adhesives do not require excessive heat and thus reduce cracks in the solar cell caused by heat.

### SUMMARY OF THE INVENTION

In cases where such a resin adhesive is used for connecting conductive connection member 105 to front electrode 103 of one of adjacent solar cells 100 and/or rear electrode 104 of the other of the adjacent solar cells 100, conductive connection member 105 may be mechanically connected to front electrode 103 and/or rear electrode 104 without melting and solidification of the solder. Therefore, it is possible to narrow the width of bus bar electrodes 103b of front electrode 103 compared to the related art or it is possible to eliminate bus bar electrodes 103b.

In this configuration, stress in solar cell 100 is more concentrated at a contact area between front electrode 103 and conductive connection member 105 in the connecting process, compared to the related art. This may increase the occurrence of cracks in the solar cell and thus lower the yield of the solar cell.

Further, the solar cell may crack due to the stress in the solar cell even though the contact area between front electrode 103 and conductive connection member 105 is designed to be large.

An aspect of the invention is to provide a solar cell and a solar cell module capable of improving the yield.

A first aspect of the invention is a solar cell including: a photoelectric conversion body including a first main surface and a second main surface opposed to the first main surface; a first electrode provided on the first main surface; a second electrode provided on the second main surface; a first conductive connection member connected with the first electrode for connecting the solar cell and another solar cell, wherein the first conductive connection member includes a conductive soft layer at an area facing the first electrode, and the first electrode includes a conductive soft layer at an area facing the first conductive connection member; and a first resin adhesive bonding the first conductive connection member to the first electrode in such a manner that the conductive soft layer of the first electrode and the conductive soft layer of the first conductive connection member abut to each other.

According to the first aspect, in a step of fixing the first conductive connection member on the first electrode, the conductive soft layer of the first electrode and the conductive soft layer of the first conductive connection member function as cushions to reduce the occurrence of cracks in the solar cell. This improves the production yield.

In the first aspect, the conductive soft layer of the first electrode and the conductive soft layer of the first conductive connection member may be in contact with each other with at least one of them being deformed. This structure increases the contact area and thus improves the electrical connection and the mechanical connection between the first electrode and the first conductive connection member.

In the first aspect, the first electrode may comprise plural narrow line electrodes. Also, the plural narrow line electrodes may be connected to each other with another narrow line electrode.

The first aspect may further include: a second conductive connection member connected with the second electrode for connecting the solar cell to another solar cell, wherein the second conductive connection member includes a conductive soft layer at an area facing the second electrode, and the second electrode includes a conductive soft layer at an area facing the second conductive connection member; and a second resin adhesive bonding the second conductive connection member to the second electrode in such a manner that the conductive soft layer of the second electrode and the conductive soft layer of the second conductive connection member abut to each other.

With this structure, the conductive soft layer of the second electrode and the conductive soft layer of the second conductive connection member function as cushions. Accordingly, the cushion effects are obtained on both of the first main surface and the second main surface in the step(s) of fixing the conductive connection member(s) on the first electrode and the second electrode. This reduces the occurrence of cracks of the first main surface and the second main surface of the solar cell and thus further improves the production yield.

In the first aspect, a curing temperature of the adhesive may be lower than the melting point of the conductive soft layer.

With this configuration, the step(s) of fixing the conductive connection member(s) on the first electrode and/or the second electrode can be performed without the conductive soft layer(s) being melted. Therefore, the conductive soft layer(s) functions as a cushion(s) adequately and a problem that the conductive soft layer(s) melts and flows to undesired portion(s) does not occur.

The resin adhesive may be a conductive adhesive containing conductive particles such as Ni, Ag, or the like. The resin adhesive may contain nonconductive particles (nonconductive materials). The resin adhesive may contain both conductive particles and nonconductive particles, or may contain neither conductive particles nor nonconductive particles.

It is preferable that the adhesive is hardening resin such as epoxy-type resin.

It is preferable that the conductive soft layer of the first electrode is made of a material softer than the main body of the first electrode.

It is preferable that the conductive soft layer of the second electrode is made of a material softer than the main body of the second electrode.

It is preferable that the conductive soft layers of the conductive connection members are made of materials softer than the conductive connection members, respectively.

It is preferable that the conductive soft layer of the first electrode, the conductive soft layer of the second electrode, and the conductive soft layers of the conductive connection members are softer than the main body of the first electrode, the main body of the second electrode, and the main bodies of the conductive connection members, respectively.

The conductive soft layer may be made of solder.

The conductive soft layer of the first electrode, the conductive soft layer of the second electrode, the conductive soft layer of the first conductive connection member, and the conductive soft layer of the second conductive connection member may be made of different materials. It is preferable that all the conductive soft layers are made of the same material. With this configuration, conditions such as temperature conditions or the like in the fixing step using the resin adhesive can be readily set, thereby facilitating the manufacture of the solar cell.

In the first aspect, at least one of the first electrode and the second electrode may extend into the conductive soft layer of the corresponding conductive connection member.

In this configuration, the first or second conductive connection member is sufficiently fixed, and this improves the mechanical connection as well as the electrical connection.

In the first aspect, the conductive soft layer of the first electrode and the conductive soft layer of the first conductive connection member may be in contact with each other with at least one of them being deformed.

This configuration increases the contact area and thus improves the electrical connection and the mechanical connection between the first electrode and the first conductive connection member.

In the first aspect, the conductive soft layer of the second electrode and the conductive soft layer of the second conductive connection member may be in contact with each other with at least one of them being deformed.

This configuration increases the contact area and thus improves the electrical connection and the mechanical connection between the second electrode and the second conductive connection member.

In the first aspect, the conductive soft layer of the first electrode and the conductive soft layer of the first conductive connection member may be in contact with each other and extend into each other.

This configuration further increases the contact area and thus further improves the electrical connection and the mechanical connection between the first electrode and the first conductive connection member.

In the first aspect, the conductive soft layer of the second electrode and the conductive soft layer of the second conductive connection member may be in contact with each other and extend into each other.

This configuration further increases the contact area and thus further improves the electrical connection and the mechanical connection between the second electrode and the second conductive connection member.

A second aspect of the invention is a solar cell module including plural solar cells according to the first aspect.

According to the second aspect, the yield of the solar cell module can be improved.

### BRIEF DESCRIPTION OF THE DRAWINGS

FIG. 1 is a top view of a solar cell module of a first embodiment of the invention.

FIG. 2 is a perspective view of the solar cell module of the first embodiment.

FIG. 3 is a sectional view of a part of the solar cell module along line A-A′ in FIG. 1.

FIG. 4A is a top view of a solar cell in the solar cell module of the first embodiment, FIG. 4B is a bottom view of the solar cell, and FIG. 4C is a sectional view of the solar cell along line B-B′ in FIGS. 4A and 4B.

FIG. 5 is a sectional view of the solar cell in the solar cell module according to the first embodiment, for explaining the connection between the solar cell and conductive connection members.

FIG. 6A is a top view of a solar cell in a solar cell module according to a second embodiment of the invention, FIG. 6B is a bottom view of the solar cell, and FIG. 6C is a sectional view of a part of the solar cell along line C-C′ in FIGS. 6A and 6B.

FIG. 7 is a sectional view of a part of the solar cell module of the second embodiment.

FIG. 8A is a top view of a solar cell of a solar cell module according to a third embodiment of the invention, FIG. 8B is a bottom view of the solar cell, and FIG. 8C is a sectional view of a part of the solar cell along line D-D′ in FIGS. 8A and 8B.

FIG. 9 is a sectional view of a part of the solar cell module of the third embodiment, for explaining the connection between the solar cell and conductive connection members.

FIG. 10A is a top view of a solar cell of a solar cell module of a fourth embodiment of the invention, FIG. 10B is a bottom view of the solar cell, and FIG. 10C is a sectional view of the solar cell with conductive connection members attached thereto, taken along line E-E′ in FIGS. 10A and FIG. 10B.

FIG. 11 is a sectional view of a solar cell of a solar cell module of a fifth embodiment of the invention, for explaining the connection between the solar cell and conductive connection members.

FIG. 12 is a sectional view of a solar cell of a solar cell module according to a sixth embodiment of the invention, for explaining the connection between the solar cell and conductive connection members.

FIG. 13A is a top view of a solar cell in a solar cell module according to a seventh embodiment of the invention, FIG. 13B is a bottom view of a solar cell, and FIG. 13C is a sectional view of the solar cell with conductive connection members attached thereto, taken along line F-F′ in FIGS. 13A and 13B.

FIG. 14A is a perspective view of a solar cell in a solar cell module according to a related art, and FIG. 14B is a sectional view of the solar cell.

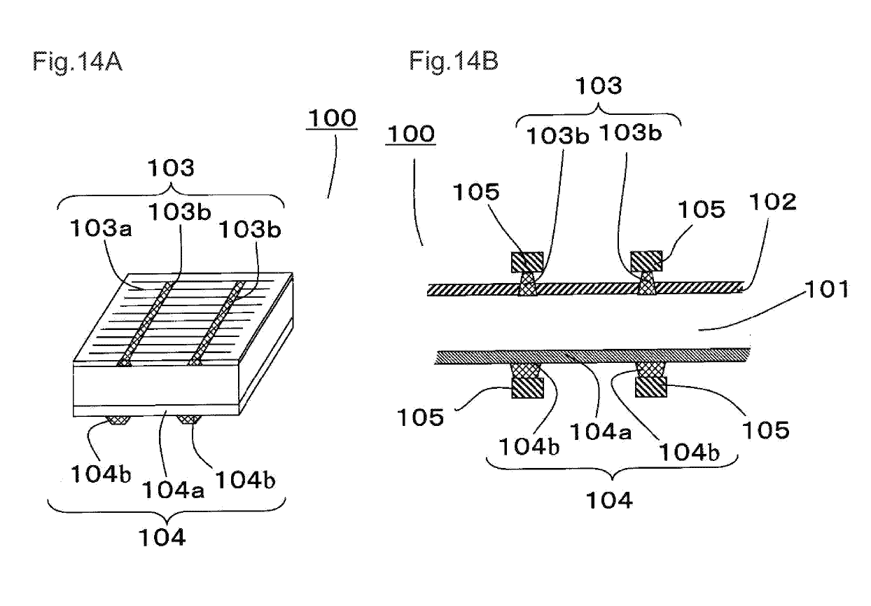

FIG. 15 is a sectional view of a part of the solar cell module according to the related art, for explaining the connection between the solar cells.

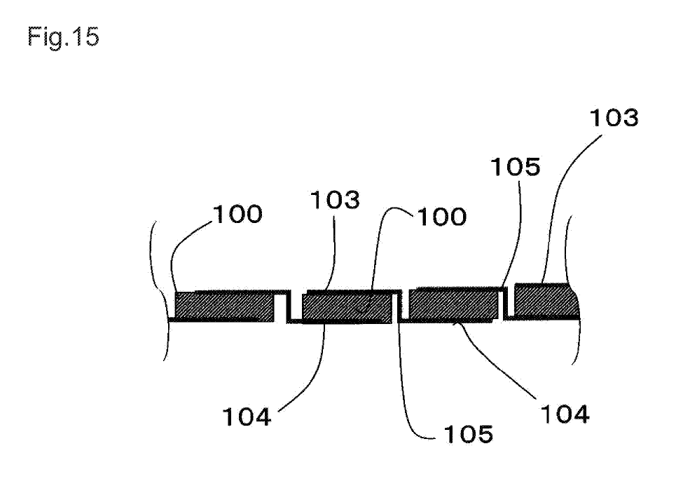

### DETAILED DESCRIPTION OF EMBODIMENTS

Descriptions are provided herein below for embodiments based on the drawings. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

Note that, the same reference numerals are used to denote the same or equivalent portions in the drawings, and the description of the portions are not repeated in order to avoid redundant description.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### First Embodiment

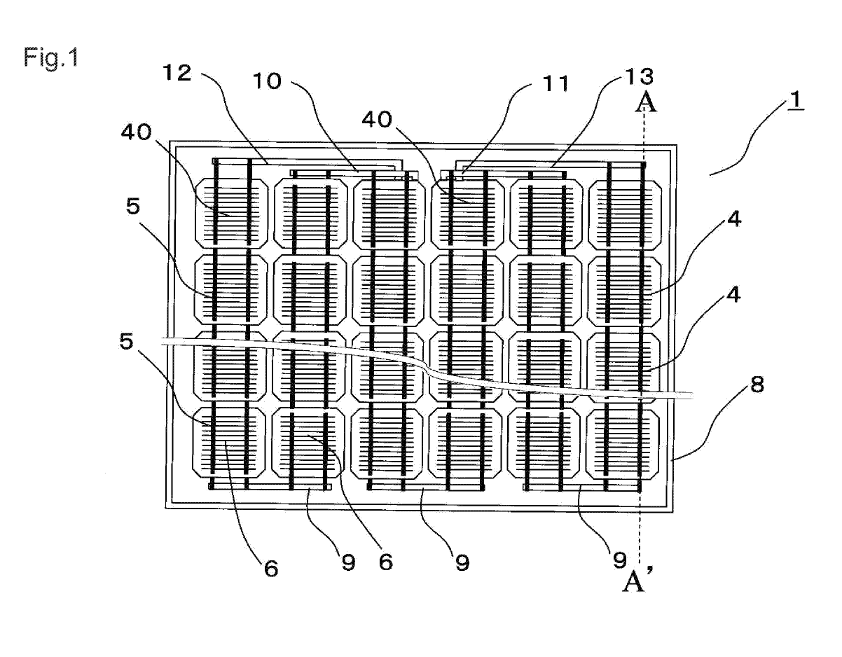

A solar cell module of a first embodiment of the invention will be described with reference to FIGS. 1 to 5.

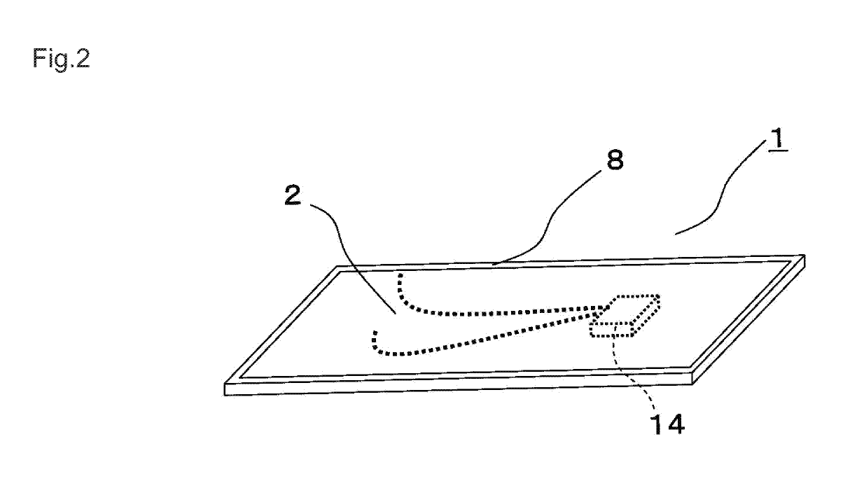

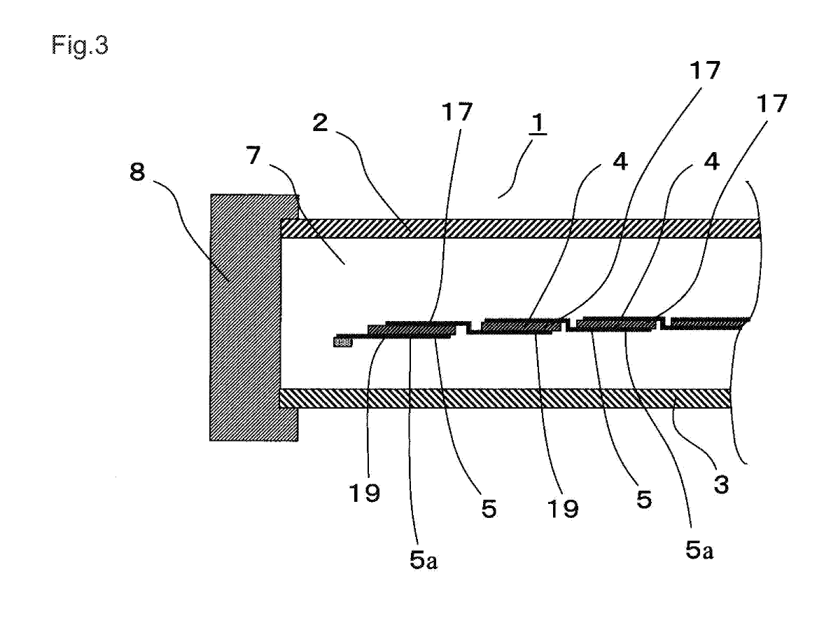

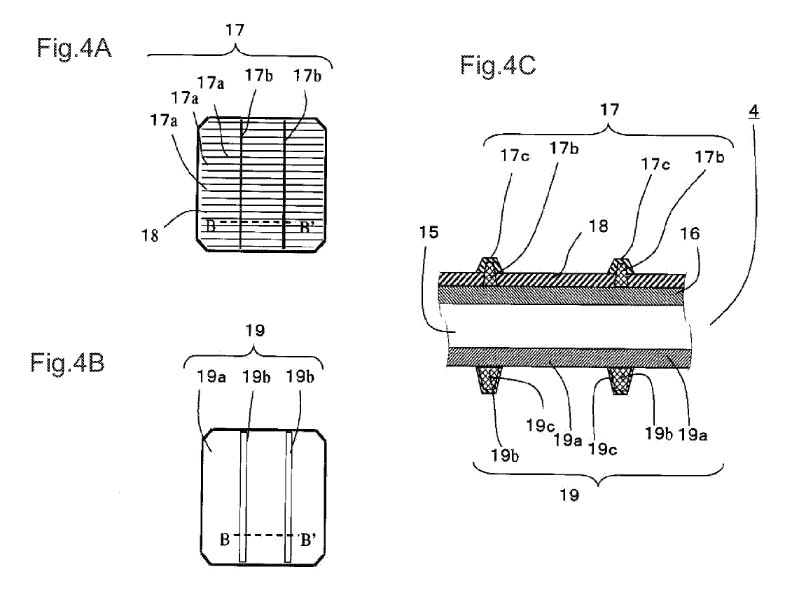

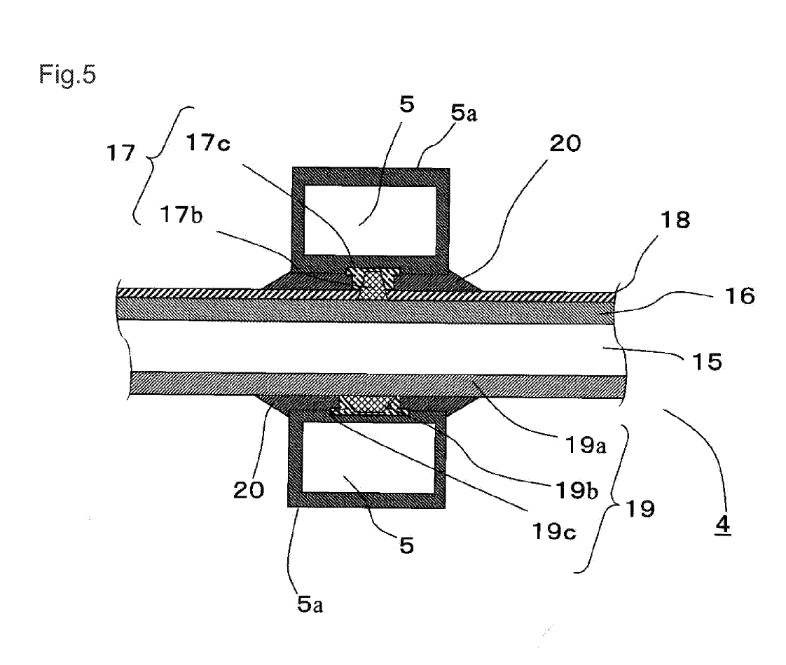

FIG. 1 is a top view of the solar cell module of the first embodiment of the invention. FIG. 2 is a perspective view of the solar cell module of the first embodiment. FIG. 3 is a sectional view of a part of the solar cell module along line A-A′ in FIG. 1. FIG. 4A is a top view of a solar cell in the solar cell module of the first embodiment, FIG. 4B is a bottom view of the solar cell, and FIG. 4C is a sectional view of the solar cell along line B-B′ in FIGS. 4A and 4B. FIG. 5 is a sectional view of a part of the solar cell module of the first embodiment, for explaining the connection between the solar cell and conductive connection members.

In FIGS. 1 to 5, reference number 1 designates a solar cell module. Solar cell module 1 includes a rectangular plate-like structure and frame body 8 made of metal such as aluminum and configured to support the outer peripheral edge of the structure (see FIG. 2). The rectangular plate-like structure includes: transparent front cover 2 such as a transparent toughened glass; rear cover 3 being a weather-resistant member made of a resin film such as polyethylene terephthalate (PET); solar cell strings 6 provided between front cover 2 and rear cover 3; filling member 7, such as ethylene vinyl acetate (EVA), filled between front cover 2 and rear cover 3 so as to fix solar cell strings 6 to front cover 2 and rear cover 3. Each solar cell string 6 is a linear string of plural solar cells 4 in which solar cells 4 are electrically connected in series with conductive connection members 5. Each conductive connection member 5 is formed in a band or strip shape having its width of 0.5 mm to 2 mm and its thickness of 100 to 300 μm and includes a core (main body) such as a flat copper wire and a conductive surface member coating on the core. The conductive surface member is a conductive soft layer (a conductive compliant layer) such as solder layer 5a made of, for example, Sn—Ag—Cu whose thickness is 5 to 40 μm.

Solar cell strings 6 are electrically connected in series in a manner that solar cell strings 6 are disposed parallel to each other with a distance therebetween. Specifically, conductive connection members 5 at one ends (lower ends in FIG. 1) of predetermined adjacent solar cell strings 6 are solder-connected to each other by strip conductive connection member 9 made from flat plate copper wire or the like whose surface is coated with a Sn—Ag—Cu solder layer having a thickness of 20 μm. In addition, conductive connection members 5 at the other ends (upper ends in FIG. 1) of different predetermined adjacent solar cell groups 6 are solder-connected to each other by L-shaped conductive connection member 10 or 11 made from flat copper wire whose surface is coated with a solder layer made of a material such as Sn—Ag—Cu having a thickness of 20 μm. In this configuration, solar cells 4 in solar cell module 1 are arranged in a matrix.

L-shaped conductive connection members (connection members for outputting the power of the solar cell module) 12 and 13 are solder-connected respectively to pairs of connection members 5 of solar cells 4 each positioned at the outermost edge of the electric power extraction side in the corresponding one of solar cell strings 6 positioned outermost. Each of L-shaped conductive connection members 12 and 13 is provided to extract electrical output from solar cell module 1 and is made of a flat copper wire coated with a solder layer made of a material such as Sn—Ag—Cu having a width of 1000 μm and a thickness of 40 μm.

Note that, an insulating member (not shown) such as an insulating sheet made of polyethylene terephthalate (PET) or the like is interposed at each point where L-shaped connection members 10 and 11 intersect with L-shaped connection members 12 and 13, respectively.

In addition, although not illustrated, a leading end portion of each of L-shaped connection members 10, 11, 12 and 13 is guided, via a notch provided at rear cover 3, to the inside of terminal box 14 provided at the upper center portion of solar cell module 1. In terminal box 14, bypass diodes (not shown) are provided to make connections between L-shaped connection members 12 and 10, between L-shaped connection members 10 and 11 and between L-shaped connection members 11 and 13, respectively.

Referring to FIGS. 4 and 5, for example, solar cells 4 each includes: p-type polycrystalline silicon substrate 15; n-type diffused layer 16 formed by heat diffusion of phosphorus into the front surface of p-type polycrystalline silicon substrate 15, which is the textured surface of substrate 15; front surface electrodes provided on n-type diffused layer 16; antireflective film 18 provide on n-type diffused layer 16 in such a manner that front surface electrode 17 is exposed from antireflective film 18; and rear surface electrode provided on the rear surface of substrate 15. Antireflective film 18 is made of a nitride silicon film (SiN), an oxide silicon film (SiO), or the like whose thickness is 60 nm, for example. Note that, in this embodiment, substrate 15 having a semiconductor junction such as a PN junction and antireflective film 18 correctively form a photoelectric conversion body configured to convert light into electricity. Note that the photoelectric conversion body may be a substrate having another type semiconductor junction coated with or without a film(s) or a layer(s).

Front surface electrode 17 is mainly made of silver. Front surface electrode 17 includes: plural fine linear finger electrodes 17a provided on and spread over substantially the entire front surface of substrate 15; and two linear bus bar electrodes 17b each connected to plural finger electrodes 17a. Finger electrodes 17a are provided parallel to each other with a distance of 2 mm between adjacent finger electrodes 17a. Each finger electrode 17a is a fine line shaped electrode which has a thickness of 10 to 30 μm and a width of 50 to 200 μm, preferably 60 to 120 μm. For example, finger electrode 17a has a thickness of 30 μm and a width of 90 μm, for example. Bus bar electrodes 17 each is a fine line shape electrode which has a thickness of 10 to 30 μm and a width of 0.1 to 1.8 mm, preferably 0.1 to 0.3 mm. For example, bus bar electrode has a thickness of 30 μm and a width of 0.3 mm.

Front surface electrode 17 is coated with solder layer (soft layer) 17c, such as Sn—Ag—Cu, having a thickness of 1 to 10 μm, for example, 5 μm. In other words, each finger electrode 17a of front surface electrode 17 includes: a core (main body) thereof; and solder layer (soft layer) 17c coating the core and thus forming the surface of finger electrode 17a, and each bus bar electrode 17b of front surface electrode 17 includes a core (main body) thereof; and solder layer (soft layer) 17c coating the core and thus forming the surface of bus bar electrode 17b. Rear surface electrode 19 includes: metal film electrode 19a provided on and spread over substantially the entire rear surface of substrate 15; two bus bar electrodes 19b provided on metal film electrode 19a. Metal film electrode 19a is made of an aluminum film whose thickness is about several μm to several mm. Linear bus bar electrode 19b is made mainly of silver and has a width of 300 μm and a thickness of 30 μm.

Each bus bar electrode 19b of rear surface electrode 19 is coated with solder layer (soft layer) 19c, such as Sn—Ag—Cu, having a thickness of 1 to 10 μm (for example, 5 μm). Bus bar electrode 19b includes: a core (main body) thereof; and solder layer (soft layer) 19c coating the core and thus forming the surface of bus bar electrode 19b.

Conductive connection member 5 is fixed to bus bar electrodes 17b of front surface electrode 17 of one of adjacent solar cells 4 and to bus bar electrodes 19b of rear surface electrode 19 of the other of the adjacent solar cells 4 with adhesive 20 made of epoxy-type resin, such that bus bar electrodes 17b of front surface electrode 17 of the one of adjacent solar cells 4 are electrically connected to bus bar electrodes 19b of rear surface electrode 19 of the other of the adjacent solar cells 4 with conductive connection member 5.

More specifically, at one end of conductive connection member 5, the one end of conductive connection member 5 is provided on bus bar electrode 17b of front surface electrode 17, wherein adhesive 20 adheres conductive connection member 5 to finger electrode 17a, bus bar electrode 17b, and antireflective film 18 while solder layer (soft layer) 5a of conductive connection member 5 is in contact with solder layer(s) (soft layer(s)) 17c of finger electrode(s) 17a and solder layer (soft layer) 17c of bus bar electrode 17b with solder layer 5a and solder layers 17c being deformed. In this structure, finger electrode 17a and bus bar electrode 17b extend into solder layer (soft layer) 5a of conductive connection member 5 without being in contact with the core of conductive connection member 5.

At the other end of conductive connection member 5, conductive connection member 5 is provided on bus bar electrodes 19b of rear surface electrode 19, wherein adhesive 20 adheres conductive connection member 5 to metal film electrode 19a and to bus bar electrodes 19b while solder layer (soft layer) 5a of conductive connection member 5 is in contact with solder layer (soft layer) 19c of bus bar electrode 19b in such a manner that solder layer 5a of conductive connection member 5 and solder layers 19c of bus bar electrode 19b are deformed.

The melting points of solder layers 5a, 17c and 19c are higher than the cure temperature of adhesive 20. Thus, in the connecting step of connecting conductive connection member 5 to front surface electrode 17 and/or rear surface electrode 19, adhesive 20 adheres while solder does not melt. For example, solder layer 5a of conductive connection member 5, the melting points of solder layer 17c of front surface electrode 17, and solder layer 19c of rear surface electrode 19 are approximately 220 degrees C., and the cure temperature of adhesive 20 is approximately 200 degrees C.

Conductive connection member 5, front surface electrode 17, and rear surface electrode 19 have, at their surface, the soft layers (solder layer 5a, solder layer 17c, and solder layer 19c) which are softer than the cores of conductive connection member 5, front surface electrode 17, and rear surface electrode 19 in at least the connecting process. Note that the soft layers (solder layer 5a, solder layer 17c, and solder layer 19c) are also softer than the cores of conductive connection member 5, front surface electrode 17, and rear surface electrode 19 in room temperature. The soft layer (solder layer 5a) of conductive connection member 5 is in contact with the soft layer (solder layer 17c) of finger electrodes 17a of front surface electrode 17 and the soft layer (solder layer 17c) of bus bar electrodes 17b, and the soft layer (solder layer 5a) of conductive connection member 5 is in contact with the soft layer (solder layer 19c) of bus bar electrodes 19b of rear surface electrode 19, which extends along substantially the entire length of bus bar electrode 17b with facing bus bar electrode 17b of front surface electrode 17.

Therefore, in the connecting step to connect conductive connection members 5 to front surface electrode 17 and rear surface electrode 19 with adhesive 20, the solder layers that face each other and are in contact with each other function as a cushion. Consequently, the occurrence of cracks in the solar cell can be reduced and the production yield can be improved, even if finger electrodes 17a and bus bar electrodes 17b of front surface electrode 17 are narrow in width and the heat stress in the cell thus tends to be concentrated.

According to the first embodiment, as described above, on the front side of solar cell 4, solder layer 5a of conductive connection member 5, which is the soft layer, is in contact with solder layer 17c of finger electrodes 17a of front surface electrode 17, which is the soft layer, and solder layer 17c of bus bar electrode 17b of front surface electrode 17, which is the soft layer. On the rear side of solar cell 4, solder layer 5a of conductive connection member 5 which is the soft layer is in contact with solder layer 19c of bus bar electrode 19b of rear surface electrode 19, which is the soft layer. Accordingly, in the contact state, solder layer 5a of conductive connection member 5 and solder layer 17c of front surface electrode 17 are deformed respectively and solder layer 5a of conductive connection member 5 and solder layer 19c of rear surface electrode 19 are deformed respectively. Therefore, as compared with a comparison structure wherein only one of conductive connection member 5 and front surface electrode 17 or only one of connection member 5 and rear surface electrode 19 is covered with a solder layer, the first embodiment reduces the occurrence of cracks in the solar cell and also increases the contact area between conductive connection member 5 and front surface electrode 17 and the contact area between conductive connection member 5 and rear surface electrode 19 to improve the contact states. Consequently, this improves the connection between conductive connection member 5 and front surface electrode 17, and the connection between conductive connection member 5 and rear surface electrode 19 thereby reducing the electric resistance of the connections.

According to the first embodiment, fine finger electrode 17a and fine bus bar electrode 17b of front surface electrode 17 extend into solder layer 5a of conductive connection member 5 while the core of fine finger electrode 17a and the core of fine bus bar electrode 17b of front surface electrode 17 are not in contact with the core of conductive connection member 5. This structure achieves an anchor effect thereby improving the connection between conductive connection member 5 and front surface electrode 17.

Note that although solder layer 17c of front surface electrode 17 and solder layer 5a of conductive connection member 5 are in contact with each other with one of them extending into the other in the first embodiment, both of them may be in contact with each other and extending into each other in a modification. This modification further increases the contact area between them and improves the contact condition between them, thereby lowering the electric resistance.

Next, a method of manufacturing the solar cell module according to the first embodiment will be described.

First, a method of manufacturing solar cell 4 will be described with reference to FIGS. 1 to 5.

In the method, first, p-type polycrystalline silicon substrate 15 whose front surface is made as a textured surface by etching is prepared.

Next, n-type diffused layer 16 extending from the textured surface of p-type polycrystalline silicon substrate 15 to a certain depth is formed by heat diffusion of phosphorus to the textured surface.

Next, antireflective film 18 is formed on n-type diffused layer 16 of p-type polycrystalline silicon substrate 15 by chemical vapor deposition (CVD) with a mask covering the area where front surface electrode 17 is to be formed.

Next, aluminum-containing paste is formed on substantially the entire rear surface of p-type polycrystalline silicon substrate 15 by screen printing, is dried, and heated at approximately 800 C, so that metal film electrode 19a made of aluminum film is formed on the substantially entire rear surface.

Next, by a screen printing method, silver paste (conductive paste) prepared by dispersing silver powder, glass frit, etc. in an organic vehicle is printed on an exposed area, which is an area where antireflective film 18 has not been formed on the front surface of p-type polycrystalline silicon substrate 15 and is printed in a predetermined pattern on metal film electrode 19a of the rear surface of p-type polycrystalline silicon substrate 15. These silver pastes are then burned at approximately 700 C, so that finger electrodes 17a and bus bar electrodes 17b which are integrally formed are provided on n-type diffused layer 16 of p-type polycrystalline silicon substrate 15 and bus bar electrodes 19b are provided on metal film electrode 19a of p-type polycrystalline silicon substrate 15. That is, front surface electrode 17 comprising finger electrodes 17a and bus bar electrodes 17b and rear surface electrode 19 comprising metal film electrode 19a and bus bar electrodes 19b are provided on the front surface and the rear surface of substrate 15 respectively.

Next, in order to coat solder layers, flux containing polyalkylene glycol resin, alcohol, amine stabilizer or the like is applied on finger electrodes 17a of front surface electrode 17, on bus bar electrodes 17b and on bus bar electrodes 19b of rear surface electrode 19 and then hot-air dried. Solar cell 4 having such flux thereon is dipped into solder bath, so that solder layers 17c, 19c are provided on finger electrodes 17a and bus bar electrodes 17b of front surface electrode 17 and on bus bar electrodes 19b of rear surface electrode 19 respectively. After providing such solder layers 17c and 19c, remaining flux on solar cell 4 is removed by laundering with organic solvent such as xylene, oluene, acetonean or the like.

Next, plural solar cells 4 manufactured as described above are prepared, and conductive connection members 5 are prepared. Note that each conductive connection member 5 is made of a flat copper wire or the like coated with solder layer (soft layer) 5a by plate processing or the like.

Next, in order to connect conductive connection member 5 to bus bar electrodes 17b of front surface electrode 17 of one of adjacent solar cells 4 and to bus bar electrodes 19b of rear surface electrode 19 of the other of the adjacent solar cells 4, adhesive 20 of epoxide-based resin is applied between the one of the adjacent solar cells 4 and conductive connection members 5 and is applied between the other of the adjacent solar cells 4 and conductive connection members 5. Then, thermocompression bonding is performed at a temperature of approximately 200 degrees C., which is lower than melting points of solder layer 5a of conductive connection member 5 and solder layer 17c of front surface electrode 17 and solder layer 19c of bus bar electrodes 19b of rear surface electrode 19 and which is the curing temperature of adhesive 20. Note that in such thermocompression bonding, solder layer 5a (soft layer) of conductive connection member 5 is in contact with solder layer 17c (soft layer) of finger electrodes 17a of front surface electrode 17 and solder layer 17c (soft layer) of bus bar electrodes 17b of front surface electrode 17, while solder layer 5a (soft layer) of conductive connection member 5 is in contact with solder layer 19c (soft layer) of bus bar electrode 19b of rear surface electrode 19.

Thus, adhesive 20 is cured in the thermocompression bonding, so that conductive connection members 5 each is mechanically and electrically connected to front surface electrode 17 of the one of adjacent solar cells 4 and to rear surface electrode 19 of the other of the adjacent solar cells 4. Using the above process, plural solar cells 4 are connected to one another with conductive connection members 5 thereby forming solar cell string 6.

After that, plural solar cell strings 6 are arranged parallel to each other, and L-shaped conductive connection members 10 and 11 and L-shaped conductive connection members (connection members for outputting the power of the solar cell module) 12 and 13 are solder-connected to conductive connection members 5 at predetermined positions, thereby forming a solar cell array. The solar cell array is disposed between transparent front cover 2 such as a transparent toughened glass and weather-resistant rear cover 3 made of a resin film such as polyethylene terephthalate (PET), with filling member 7 such as ethylene vinyl acetate (EVA) filled between front cover 2 and rear cover 3, so as to form a rectangular plate-like structure. Then, the rectangular plate-like structure is heated. After that, metal frame body 8 and terminal box 14 is attached to the rectangular plate-like structure, so that solar cell module 1 is completed.

In the manufacturing method of this embodiment, solder layers 5a serving as soft layers of conductive connection members 5 are in contact with solder layers 17c serving as soft layers of finger electrodes 17a of front surface electrode 17 and solder layers 17c serving as soft layers of bus bar electrodes 17b of front surface electrode 17, while solder layers 5a serving as soft layers of conductive connection members 5 are in contact with solder layers 19c serving as soft layers of bus bar electrodes 19b of rear surface electrode 19. Therefore, even in a structure where thermal stress tends to be concentrated due to narrow finger electrodes 17a and narrow bus bar electrodes 17b of front surface electrode 17, the occurrence of cracks in the solar cell can be reduced in the process of connecting conductive connection members 5 to front surface electrode 17 and to rear surface electrode 19 with adhesive 20. This improves the production yield.

### Second Embodiment

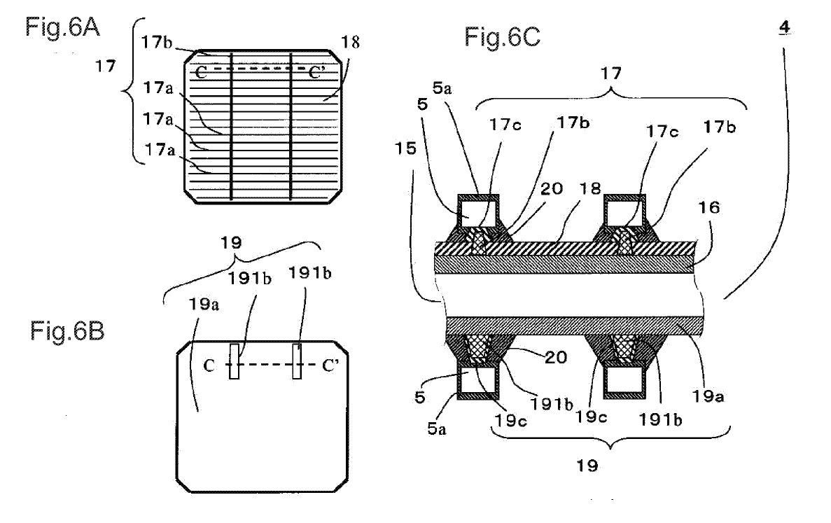

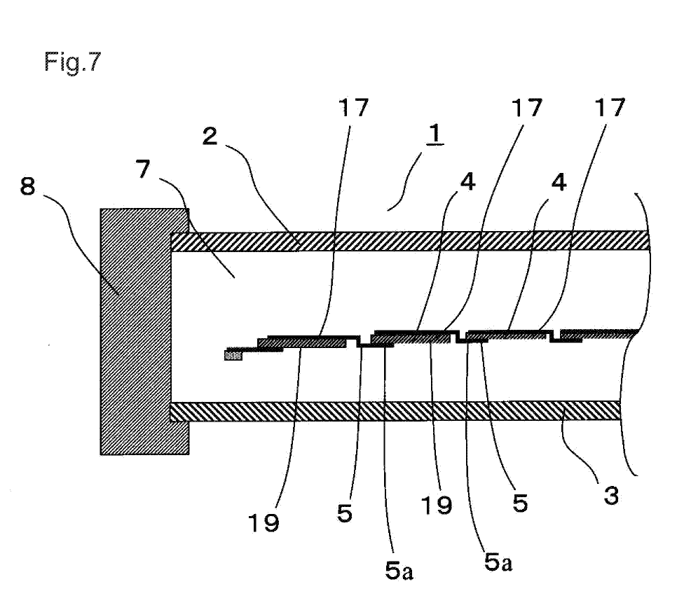

A solar cell module of the second embodiment of the invention will be described with reference to FIGS. 6A, 6B, 6C and 7. FIG. 6A is a top view of a solar cell in the solar cell module, FIG. 6B is a bottom view of the solar cell, and FIG. 6C is a sectional view of a part of the solar cell with connection members connected thereto taken along line C-C′ in FIGS. 6A and 6B. FIG. 7 is a sectional view of a part of the solar cell module. Note that differences from the first embodiment are mainly described in the second embodiment.

The second embodiment is different from the first embodiment in that bus bar electrodes of rear surface electrode 19 are shorter than those of the first embodiment in the longitudinal direction and are formed in the vicinity of the edge of the rear surface of solar cell 4. The other configurations are the same as those of the first embodiment and are designated in FIGS. 6A to 7 by the same reference numerals as those of the first embodiment.

As shown in FIGS. 6A to 7, regarding the connection of conductive connection members 5 to the rear surface of solar cell 4, conductive connection members 5 are electrically connected to bus bar electrodes 191b and 191b provided in the vicinity of the edge of solar cell 4.

In this second embodiment, bus bar electrodes 191b and 191b of rear surface electrode 19 are provided partially along bus bar electrodes 17b and 17b of front surface electrode 17, but are not provided along the entire length of bus bar electrodes 17b and 17b. Thus, in the thermocompression bonding process, it is preferable to dispose pads or the like on the area on metal film electrode 19a where bus bar electrodes 17b and 17b of front surface electrode 17 are opposed to but bus bar electrodes 191b and 191b of rear surface electrode 19 do not exist.

According to this second embodiment, the same effects as in the first embodiment can be obtained.

### Third Embodiment

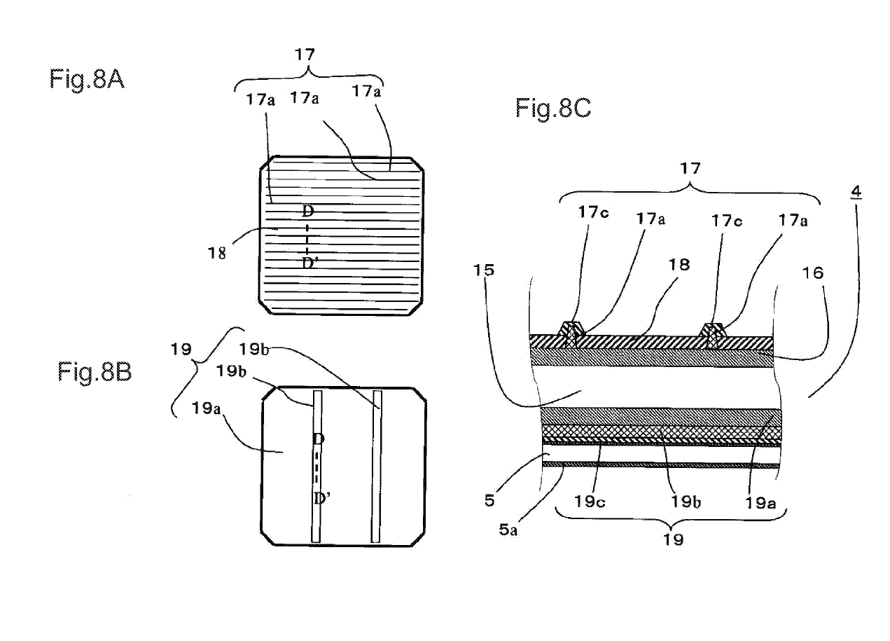

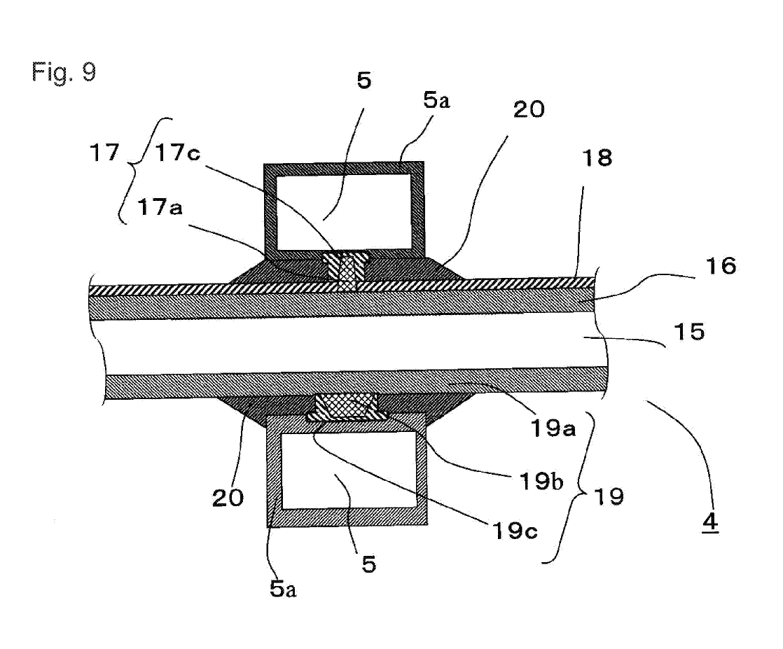

A solar cell module of the third embodiment of the invention will be described with reference to FIGS. 8A, 8B, 8C, and 9. FIG. 8A is a top view of a solar cell of the solar cell module, FIG. 8B is a bottom view of the solar cell, and FIG. 8C is a sectional view of a part of the solar cell along line D-D′ in FIGS. 8A and 8B. FIG. 9 is a sectional view of a part of the solar cell module of the third embodiment, for explaining the connection between the solar cell and conductive connection members. Note that differences from the first embodiment are mainly described in the third embodiment.

The third embodiment is different from the first embodiment in that front surface electrode 17 has no bus bar electrode (that is, the front surface electrode 17 has no bus bar structure). The other configurations in the third embodiment are the same as those of the first embodiment and are designated in FIGS. 8A to 9 by the same reference numerals.

With reference to FIGS. 8A to 9, front surface electrode 17 of solar cell 4 will be described below.

Front surface electrode 17 is made mainly of silver, and comprises plural fine linear finger electrodes 17a spreading over substantially the entire front surface of substrate 15. In the third embodiment, finger electrodes 17a are fine line-shaped electrodes with a distance of 2 mm therebetween and each having a thickness of 10 to 30 μm (for example, 30 μm) and a width of 50 to 200 μm, preferably 60 to 120 μm (for example, 90 μm).

The surface of front surface electrode 17 is coated with solder layer (soft layer) 17c made of a material such as Sn—Ag—Cu having a thickness of 1 to 10 μm (for example, 5 μm). In other words, each finger electrode 17a of front surface electrode 17 includes: a core (main body) thereof and solder layer (soft layer) 17c coating the core and thus comprising the surface of finger electrode 17a. Rear surface electrode 19 has the same structure as the first embodiment, that is, rear surface electrode 19 includes: metal film electrode 19a formed on the substantially entire rear surface of substrate 15; two wide bus bar electrodes 19b and 19b provided on metal film electrode 19a. Metal film electrode 19a is made of an aluminum film whose thickness is about several μm to several mm. Bus bar electrode 19b is made mainly of silver and has a width of 0.3 mm and a thickness of 30 μm.

The surface of bus bar electrode 19b of rear surface electrode 19 is coated with solder layer (soft layer) 19c made of a material such as Sn—Ag—Cu having a thickness of 1 to 10 μm (for example, 5 μm). In other words, bus bar electrode 19b of rear surface electrode 19 includes: the core (main body) thereof; and solder layer (soft layer) 19c covering the core and thus comprising the surface of bus bar electrode 19b.

Bus bar electrodes 17b and 17b of front surface electrode 17 of one of adjacent solar cells 4 and 4 is electrically connected to bus bar electrodes 19b and 19b of rear surface electrode 19 with conductive connection members 5 and 5, in such a manner that conductive connection members 5 and 5 are fixed to bus bar electrodes 17b and 17b and to bus bar electrodes 19b and 19b with adhesive 20 made of epoxy-type resin.

More specifically, regarding one end of conductive connection member 5, the one end of conductive connection member 5 is provided on finger electrodes 17a of front surface electrode 17 with a bond of adhesive 20 between antireflective film 18 and conductive connection member 5 and between finger electrodes 17a and conductive connection member 5 in such a manner that solder layer (soft layer) 5a of conductive connection member 5 is in contact with solder layers (soft layers) 17c of finger electrodes 17a and finger electrodes 17a are digged into solder layer (soft layer) 5a of conductive connection member 5.

Regarding the other end of conductive connection member 5, conductive connection member 5 is provided on bus bar electrodes 19b of rear surface electrode 19 with a bond of adhesive 20 between metal film electrode 19a and conductive connection member 5 and between bus bar electrode 19b and conductive connection member 5, in such a manner that solder layer (soft layer) 5a of conductive connection member 5 is in contact with solder layers (soft layers) 19c of bus bar electrode 19b.

The melting points of solder layer 5a, 17c, and 19c are higher than the curing temperature of adhesive 20. In the process of connecting conductive connection members 5 and 5 to front surface electrode 17 and to rear surface electrode 19, the bonding by using adhesive 20 is achieved without melting the solders. For example, the melting temperatures of solder layer 5a of conductive connection member 5, solder layer 17c of front surface electrode 17, and solder layer 19c of rear surface electrode 19 are approximately 220 degrees C., whereas the curing temperature of adhesive 20 is approximately 200 degrees C.

In this third embodiment, conductive connection member 5, front surface electrode 17, and rear surface electrode 19 have, at their surfaces, solder layer (soft layer) 5a, solder layer (soft layer) 17c, solder layer (soft layer) 19c which are made of materials softer than the cores of conductive connection member 5, front surface electrode 17, and rear surface electrode 19, respectively, at room temperature. Solder layer 5a serving as a soft layer of conductive connection member 5 is in contact with solder layer(s) 17c serving as soft layer(s) of finger electrode(s) 17a of front surface electrode 17 and solder layer 5a serving as a soft layers of conductive connection member 5 is in contact with solder layer 19c serving as a soft layer of bus bar electrode 19b of rear surface electrode 19. With this configuration, cushioning characteristics of the solder layers that face (contact with) each other reduce the occurrence of cracks in solar cell 4 in the process of connecting conductive connection members 5 to front surface electrode 17 and to rear surface electrode 19 with adhesive 20, even in a structure where the thermal stress in solar cell 4 tends to be concentrated due to narrow finger electrodes 17a of front surface electrode 17. This improves the production yield.

Further, as described above, solder layer 5a serving as the soft layer of conductive connection member 5 is contact with solder layer 17c serving as the soft layer of finger electrode 17a of front surface electrode 17 and solder layer 17c serving as the soft layer of bus bar electrodes 17b of front surface electrode 17, and solder layer 5a serving as the soft layer of conductive connection member 5 is contact with solder layer 19c serving the soft layer of bus bar electrode 19b of rear surface electrode 19. In this structure, solder layer 5a of conductive connection member 5 is contact with solder layer 17c of front surface electrode 17 with both solder layer 5a and solder layer 17c being deformed and solder layer 5a of conductive connection member 5 is contact with solder layer 19c of rear surface electrode 19 with both solder layer 5a and solder layer 17c being deformed in the connecting process. Accordingly, in addition to reducing the occurrence of cracks in solar cell 4, this structure increases the contact area and improves the contact condition, as compared to a comparative structure where one of conductive connection member 5 and front surface electrode 17 is coated with a solder layer or one of conductive connection member 5 and rear surface electrode 19 is coated with a solder layer. Therefore, the contact between conductive connection member 5 and front surface electrode 17 and the contact between conductive connection member 5 and rear surface electrode 19 are improved, and this reduces the electric resistance of these contacts.

Further, according to this embodiment, narrow finger electrodes 17a of front surface electrode 17 are not in contact with the core of conductive connection member 5 and extend into solder layer 5a of conductive connection member 5, and this achieves an anchor characteristic, that is, narrow finger electrodes 17a are anchored to conductive connection member 5. Therefore, this brings about a preferable connection between conductive connection member 5 and front surface electrode 17.

Note that the soft layers that are in contact with each other may extend into each other. In this modification, the contact area is further increased and the contact condition is further improved, this reduces the electric resistance of the contact.

The method of manufacturing the solar cell module of the third embodiment is the same as or similar to that of the first embodiment, and thus can achieve the same effects as the manufacturing method of the first embodiment.

### Fourth Embodiment

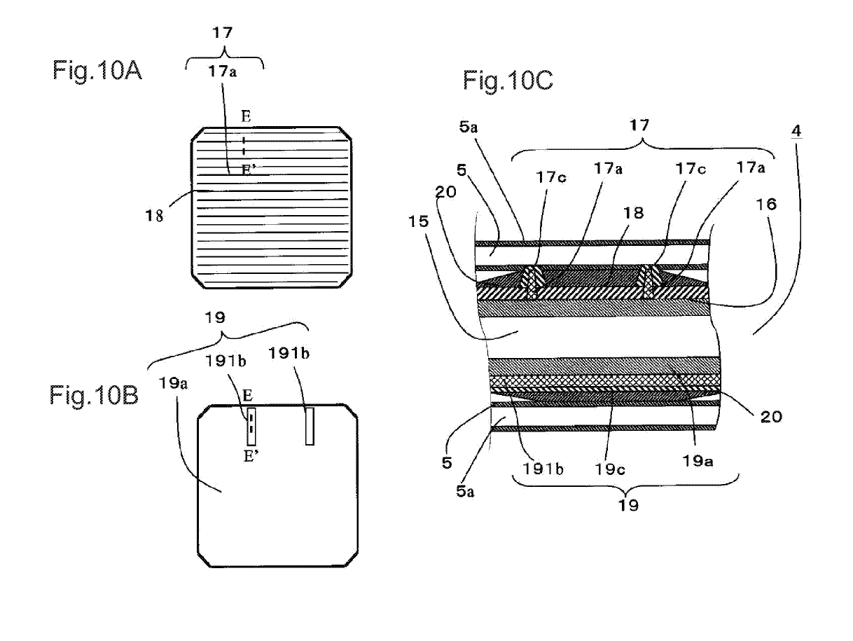

Next, a solar cell module according to the fourth embodiment of the invention will be described with reference to FIGS. 10A to 10C. FIG. 10A is a top view of a solar cell of the solar cell module, FIG. 10B is a bottom view of the solar cell, and FIG. 10C is a sectional view of the solar cell with conductive connection members attached thereto, taken along line E-E′ in FIGS. 10A and 10B. Note that in the fourth embodiment, differences from the third embodiment will be mainly described below.

The fourth embodiment is different from the third embodiment in that rear surface electrode 19 having the same configuration as that of the second embodiment, that is, the bus bar electrodes of rear surface electrode 19 have a short length along the longitudinal direction thereof and are formed in the vicinity of the edge of the rear surface of solar cell 4. The other configurations in the fourth embodiment are the same as those of the third embodiment and are designated in FIGS. 10A to 10C by the same reference numerals as those of the third embodiment.

As shown in FIGS. 10A to 10C, regarding the connection of conductive connection members 5 and 5 to the rear surface of solar cell 4, conductive connection members 5 and 5 are electrically connected to bus bar electrodes 191b and 191b which are provided in the vicinity of the edge of the rear surface of the solar cell 4.

In the fourth embodiment, no bus bar electrode of front surface electrode 17 is provided along the entire length of bus bar electrodes 191b and 191b of rear surface electrode 19. Accordingly, in the thermocompression bonding process, it is preferable to dispose pads or the like on the front surface at the area opposed to bus bar electrodes 191b and 191b.

According to the fourth embodiment, the same effects as in the third embodiment can be obtained.

### Fifth Embodiment

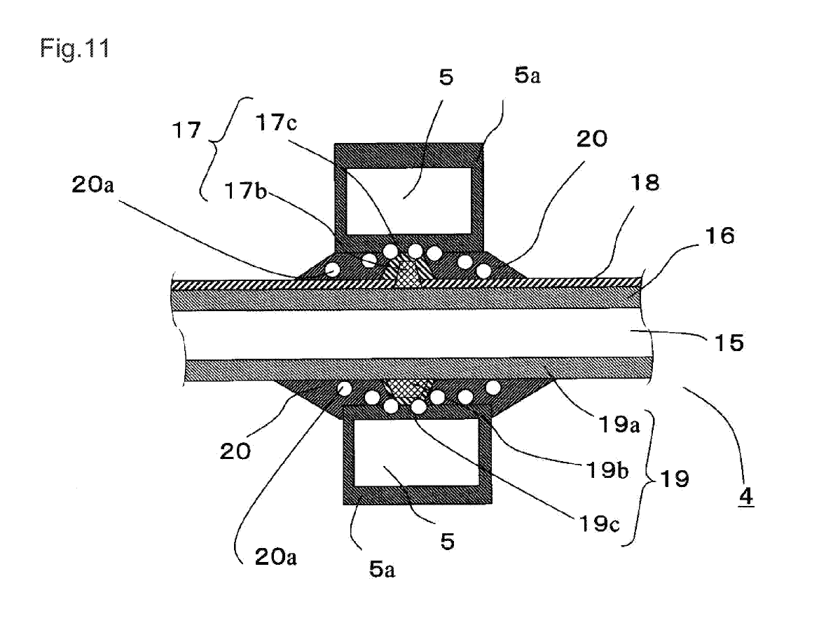

A solar cell module of the fifth embodiment of the invention will be described below with reference to FIG. 11. FIG. 11 is a sectional view of a solar cell in the solar cell module. Note that, in the fifth embodiment, differences from the first embodiment will be mainly described below.

The fifth embodiment is different from the first embodiment in that adhesive 20 includes therein conducting particles 20a, that is, adhesive 20 is a so-called electrically-conducting adhesive and finger electrodes 17a and bus bar electrodes 17b are do not extend into solder layer (soft layer) 5a and 5a of conductive connection members 5 and 5. The other configurations are the same as in the first embodiment and are designated by the same reference numerals.

Conducting particles 20a are nickel particles or silver particles and may be Ag-coated nickel particles, metal-coated plastic particles such as Ag-coated plastic particles, silver-coated plastic particles, or the other conducting particles. The maximum particle diameter of conducting particles 20a is, for example, 20 μm.

Bus bar electrodes 17b of front surface electrode 17 of one of adjacent solar cells 4 and 4 are electrically connected to bus bar electrodes 19b of rear surface electrode 19 of the other of the adjacent solar cells 4 and 4 with conductive connection members 5 and 5 in such a manner that adhesive 20 of epoxy-type resin bonds conductive connection members 5 and 5 to solar cells 4 and 4.

More specifically, regarding one end of conductive connection member 5, the one end of conductive connection member 5 is provided on bus bar electrode 17b of front surface electrode 17 with a bond of adhesive 20 between antireflective film 18 and conductive connection member 5, between finger electrode(s) 17a and conductive connection member 5, and between bus bar electrode 17b and conductive connection member 5, wherein solder layer (soft layer) 5a of conductive connection member 5 is in contact with solder layer (soft layer) 17c of finger electrode(s) 17a and with solder layer (soft layer) 17c of bus bar electrode 17b.

Regarding the other end of conductive connection member 5, the other end of conductive connection member 5 is provided on bus bar electrode 19b of rear surface electrode 19 with a bond of adhesive 20 between metal film electrode 19a and conductive connection member 5 and between bus bar electrode 19b and conductive connection members 5, wherein solder layer (soft layer) 5a of conductive connection member 5 is in contact with solder layer (soft layer) 19c of bus bar electrode 19b.

In the fifth embodiment, conductive connection member 5, front surface electrode 17, and rear surface electrode 19 have, at their surfaces, solder layer (soft layer) 5a, solder layer (soft layer) 17c, solder layer (soft layer) 19c which are softer than the cores of conductive connection member 5, front surface electrode 17, and rear surface electrode 19, respectively, at room temperature. Solder layer 5a serving as a soft layer of conductive connection member 5 is opposed to and in contact with solder layer(s) 17c serving as soft layer(s) of finger electrode(s) 17a of front surface electrode 17 and is opposed to and in contact with solder layer 17c serving as a soft layer of bus bar electrode 17b of front surface electrode 17. Further, solder layer 5a serving as a soft layer of conductive connection member 5 is opposed to and in contact with solder layer 19c serving as a soft layer of bus bar electrode 19b of rear surface electrode 19. With this configuration, cushioning characteristics of the solder layers that face (contact with) each other reduce the occurrence of cracks in solar cell 4 in the process of connecting conductive connection members 5 to front surface electrode 17 and to rear surface electrode 19 with adhesive 20, even in a structure where the thermal stress in solar cell 4 tends to be concentrated due to narrow finger electrodes 17a and narrow bus bar electrodes 17b of front surface electrode 17 with conducting particles 20a. This improves the production yield.

The fifth embodiment is different from the first embodiment in that finger electrodes 17a and bus bar electrodes 17b do not extend into solder layer (soft layer) 5a of conductive connection member 5. However, conducting particles 20a do extend into solder layer 5a of conductive connection member 5 and into solder layer 17c of front surface electrode 17 on the front side, and conducting particles 20a extend into solder layer 5a of conductive connection member 5 and into solder layer 19c of rear surface electrode 19 on the rear side, thereby improving the contact condition therebetween. Accordingly, this improves the electric connection between conductive connection member 5 and front surface electrode 17 and the electric connection between conductive connection member 5 and rear surface electrode 19, thereby reducing the electric resistances thereof. Further, anchor characteristic of conducting particles 20a extending into members 5c and 17c and members 5c and 19c brings about a preferable connection between conductive connection member 5 and front surface electrode 17 and a preferable connection between conductive connection member 5 and rear surface electrode 19.

Although finger electrode 17a and bus bar electrode 17b do not extend into solder layer (soft layer) 5a of conductive connection member 5 in the fifth embodiment, finger electrode 17a and bus bar electrode 17b may extend into solder layer (soft layer) 5a of conductive connection member 5 like the first embodiment.

Note that it is preferable to set the condition of thermocompression bonding in addition to the thickness of solder layer 5a of conductive connection member 5, the thickness of solder layer 17c of front surface electrode 17, and the thickness of solder layer 19c of rear surface electrode 19, in order to prevent conducting particles 20a from being in contact with the core of conductive connection member 5, the core of front surface electrode 17, and the core of rear surface electrode 19.

The method of manufacturing the solar cell module in the fifth embodiment is the same as or similar to that of the first embodiment, and thus can achieve the same effects as the manufacturing method of the first embodiment.

### Sixth Embodiment

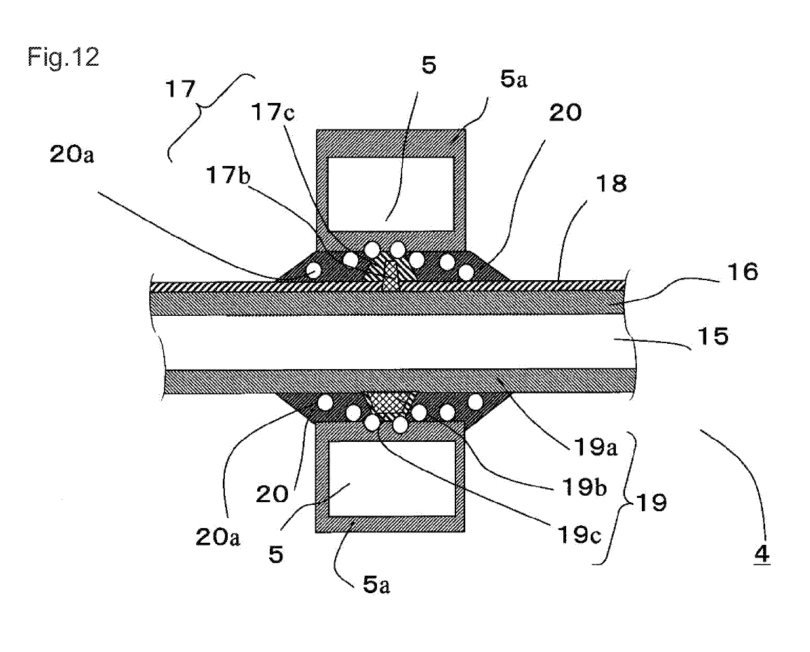

A solar cell module of the sixth embodiment of the invention will be described with reference to FIG. 12. FIG. 12 is a cross sectional view of a solar cell of the solar cell module according to the sixth embodiment. Note that differences from the fifth embodiment will be mainly described below in the sixth embodiment.

The sixth embodiment is different from the fifth embodiment in that front surface electrode 17 includes no bus bar electrode (that is, front surface electrode 17 has no-bus-bar structure). The other configurations are the same as in the fifth embodiment and are designated by the same reference numerals.

The sixth embodiment has front surface electrode 17 having the no-bus-bar structure and can achieves the same effects as in the fourth embodiment.

### Seventh Embodiment

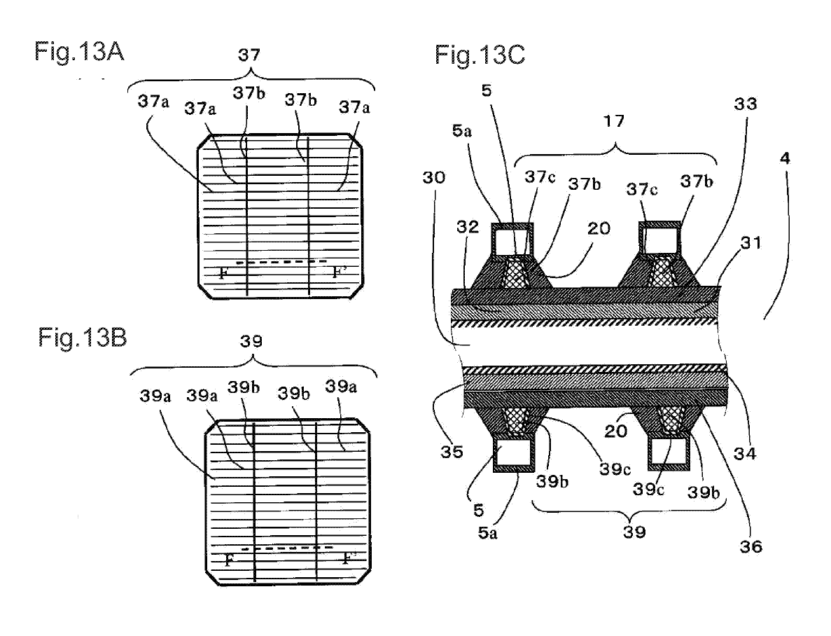

A solar cell module of the seventh embodiment of the invention will be described below with reference to FIGS. 13A to 13C. FIG. 13A is a top view of a solar cell in the solar cell module, FIG. 13B is a bottom view of the solar cell, and FIG. 13C is a sectional view of the solar cell with conductive connection members attached thereto taken along line F-F′ in FIGS. 13A and 13B. Note that in the seventh embodiment, differences from the first embodiment will be mainly described below.

In the seventh embodiment, each of solar cells 4 is a HIT solar cell. Either of a front surface electrode or a rear surface electrode of solar cell 4 has plural fine linear finger electrodes and two bus bar electrodes connected with the finger electrodes.

As shown in FIGS. 13A to 13C, solar cell 4 is a so-called HIT solar cell, wherein i-type amorphous silicon layer 31, p-type amorphous silicon layer 32, and transparent conductive layer 33 such as ITO are provided in this order on substantially the entire region of the textured front surface of n-type single-crystalline silicon substrate 30 and wherein i-type amorphous silicon layer 34, n-type amorphous silicon layer 35, and transparent conductive layer 36 such as ITO are provided in this order on substantially the entire region of a textured rear surface of substrate 30. Front surface electrode 37 is provided on transparent conductive layer 33, and rear surface electrode 39 is provided on transparent conductive layer 36.

Front surface electrode 37 is mainly made of silver. Front surface electrode 37 includes: plural fine linear finger electrodes 37a disposed on and spread over substantially the entire surface of transparent conductive layer 33; and two linear bus bar electrodes 37b and 37b each connected to plural finger electrodes 37a. Finger electrodes 37a are provided every 2 mm and each is a fine line shaped electrode whose thickness is 10 to 30 μm (for example, 30 μm) and whose width is 50 to 200 μm, preferably 60 to 120 μm (for example, 90 μm). Bus bar electrodes 37 each is a fine line shape electrode whose thickness is 10 to 30 μm (for example, 30 μm) and whose width is 0.1 to 1.8 mm, preferably 0.1 to 0.3 mm (for example, 0.3 mm). Front surface electrode 37 is coated with solder layer (soft layer) 37c, such as Sn—Ag—Cu, having a thickness of 1 to 10 μm (for example, 5 μm). In other words, each finger electrode 37a includes: a core (main body) thereof; and solder layer (soft layer) 37c coating the core and thus comprising the surface of finger electrode 37a, and each bus bar electrode 37b includes: a core (main body) thereof; and solder layer (soft layer) 37c coating the core and comprising the surface of bus bar electrode 37b.

Rear surface electrode 39 is mainly made of silver. Rear surface electrode 39 includes: plural fine linear finger electrodes 39a provided on and spread over substantially the entire surface of transparent conductive layer 36; two fine bus bar electrodes 39b each connected with plural finger electrodes 39a. In this embodiment, finger electrodes 39a are located every 2 mm and each is a fine line shaped electrode whose thickness is 10 to 30 μm (for example, 30 μm) and whose width is 50 to 200 μm, preferably 60 to 120 μm (for example, 90 μm). Bus bar electrodes 39b each is a fine lined shape electrode whose thickness is 10 to 30 μm (for example, 30 μm) and whose width is 0.1 to 1.8 mm, preferably 0.1 to 0.3 mm (for example, 0.3 mm).

Rear surface electrode 39 is coated with solder layer (soft layer) 39c, such as Sn—Ag—Cu, having a thickness of 1 to 10 μm, (for example, 5 μm). That is, each finger electrode 39a includes: a core (main body) thereof and solder layer (soft layer) 39c coating the core and thus comprising the surface of finger electrode 39a, and each bus bar electrode 39b includes: a core (main body) thereof; and solder layer (soft layer) 39c coating the core and thus comprising the surface of bus bar electrode 39b.

Bus bar electrodes 37b and 37b of front surface electrode 37 of one of adjacent solar cells 4 and 4 are electrically connected to bus bar electrodes 39b and 39b of rear surface electrode 39 of the other of the adjacent solar cells 4 and 4 with conductive connection members 5 and 5, in such a manner that conductive connection members 5 and 5 are fixed to bus bar electrodes 37b and 37b and bus bar electrodes 39b and 39b with adhesive 20 made of epoxy-type resin.

That is, regarding one end of conductive connection member 5, the one end of conductive connection member 5 is provided on the bus bar electrodes 37b and 37b of front surface electrode 37 with a bond of adhesive 20 between transparent conductive layer 33 and conductive connection member 5 and between finger electrode(s) 37a and conductive connection member 5 and between bus bar electrode 37b and conductive connection member 5, wherein solder layer (soft layer) 5a of conductive connection member 5 is in contact with solder layer (soft layer) 37c of finger electrode(s) 37a and with solder layer (soft layer) 37c of bus bar electrode 37b in such a manner that finger electrode(s) 37a and bus bar electrode 37b extend into solder layer (soft layer) 5a of conductive connection member 5.

Regarding the other end of conductive connection member 5, conductive connection member 5 is provided on bus bar electrode 39b of rear surface electrode 39 with a bond of adhesive 20 between transparent conductive layer 36 and conductive connection member 5 and between finger electrode(s) 39a and conductive connection member 5 and between bus bar electrode 39b and conductive connection member 5, wherein solder layer (soft layer) 5a of conductive connection member 5 is in contact with solder layer (soft layer) 39c of finger electrode(s) 39a and with solder layer (soft layer) 39c of bus bar electrode 39b in such a manner that finger electrode(s) 39a and bus bar electrode 39b extend into solder layer (soft layer) 5a of conductive connection member 5.

The melting points of solder layers 5a, 37c, and 39c are higher than the curing temperature of adhesive 20. In the process of connecting conductive connection members 5 and 5 to front surface electrode 37 and to rear surface electrode 39, the bonding using adhesive 20 is thus achieved without melting the solders. For example, the melting points of solder layer 5a of conductive connection member 5, solder layer 37c of front surface electrode 37, solder layer 39c of rear surface electrode 39 are approximately 220 degrees C., whereas the curing temperature of adhesive 20 is approximately 200 degrees C.

In this embodiment, conductive connection member 5, front surface electrode 37, and rear surface electrode 39 have, at their surface, solder layer 5a (soft layer), solder layer 37c (soft layer), solder layer 39c (soft layer) which are made of materials softer than the cores of conductive connection member 5, front surface electrode 17, and rear surface electrode 19, respectively, at room temperature. On the front side, Solder layer 5a serving as the soft layer of conductive connection member 5 is in contact with solder layer 37c serving as the soft layer of finger electrodes 37a of front surface electrode 37 and with solder layer 37c serving as the soft layer of bus bar electrode 37b of front surface electrode 37. On the rear side, solder layer 5a serving as the soft layer of conductive connection member 5 is contact with solder layer(s) 39c serving as the soft layer(s) of finger electrode(s) 39a of rear surface electrode 39 and with solder layer 39c serving as the soft layer of bus bar electrode 39b of rear surface electrode 39. With this configuration, cushioning characteristics of the solder layers that face (contact with) each other reduce the occurrence of cracks in solar cell 4 in the process of connecting conductive connection members 5 to front surface electrode 37 and to rear surface electrode 39 with adhesive 20. This improves the production yield.

Further, according to this embodiment, solder layer 5a of conductive connection member 5 and solder layer 37c of front surface electrode 37 are in contact with each other with both being deformed while solder layer 5a of conductive connection member 5 and solder layer 39c of rear surface electrode 39 are in contact with each other with both being deformed.

Accordingly, this structure increases the contact area and improves the contact condition, as compared to a comparative structure where one of conductive connection member 5 and front surface electrode 37 is coated with a solder layer or one of conductive connection member 5 and rear surface electrode 39 is coated with a solder layer. Therefore, the contact between conductive connection member 5 and front surface electrode 37 and the contact between conductive connection member 5 and rear surface electrode 39 are improved, and this reduces the electric resistance of these contacts.

Further, according to this embodiment, narrow finger electrodes 37a and narrow bus bar electrodes 37b of front surface electrode 37 extend into solder layer 5a of conductive connection member 5, and narrow finger electrodes 39a and narrow bus bar electrodes 39b of rear surface electrode 39 extend into solder layer 5a of conductive connection member 5, thereby achieving anchor characteristics. Therefore, this brings about a preferable connection between conductive connection member 5 and front surface electrode 37 and a preferable connection between conductive connection member 5 and rear surface electrode 39.

According to the manufacturing method of this embodiment, the same effects as in the first embodiment can be obtained.

Although the solder of Sn—Ag—Cu alloy is used as the conductive soft layer in the above embodiments, various types of solders such as Au—Si alloy, Au—Ge alloy, Au—Sn alloy, Sn—Cu alloy, Sn—Ag alloy, Sn—Au alloy, Sn—Ag—Cu alloy, Pb—Au alloy, Sn—Ag—In alloy, Sn—Pb alloy, or the like may be used.

As described above, the resin adhesive may be an electrical insulation adhesive or an electrical conductive adhesive.

In the fifth and sixth embodiments, the electrically-conducting adhesive containing the conducting particles such as Ni, Ag or the like is used as the resin adhesive. However, the electrically-conducting adhesive may include nonconductive particles (nonconductive materials) such as SiO₂, may include both conducting particles and nonconductive particles, or may include neither conducting particles nor nonconductive particles.

In the first to seventh embodiments, the conductive soft layer is provided on the entire area of the front surface electrode. However, the conductive soft layer may be provided only on an opposed area that faces the conductive connection member, or may be provided only on the opposed area in such a manner that the conductive soft layer is not provided on a part of the opposed area.

In the above embodiments, the conductive soft layer is provided on the front surface electrode and on the rear surface electrode. However, a structure in which the conductive soft layer is provided on either the front surface electrode or the rear surface electrode can achieve similar effects to the above embodiment.

Although the solar cells in the above embodiments are described using polycrystalline solar cells and HIT solar cells, various solar cells such as single-crystalline solar cells can be appropriately used.

Further, the solar cell module of the invention is not limited to the above embodiments. For example, the solar cell module of the invention may have no frame body although the solar cell module in the above embodiments has frame body 8.

The invention may be applied to a bifacial solar cell module, for example, each of front cover 2 and rear cover 3 may be made of a glass plate.

The number of the bus bar electrodes of the front surface electrode and the number of the bus bar electrodes of the rear surface electrode may be appropriately changed, respectively.

The embodiment disclosed in this description is to be considered as only exemplary and not intended to impose any limitation. It is intended that the scope of the invention is not limited by the embodiment described above, but by the scope of claims appended hereto, and that the scope of the invention include all modifications within the scope of claims and the equivalents to the claims.

What is claimed is:

1. A solar cell comprising:
a photoelectric conversion body including a first main surface and a second main surface opposed to the first main surface;
a first electrode provided on the first main surface;
a second electrode provided on the second main surface;
a first conductive connection member connected with the first electrode for connecting the solar cell and another solar cell, wherein the first conductive connection member includes a conductive soft layer at an area facing the first electrode, and the first electrode includes a conductive soft layer at an area facing the first conductive connection member; and
a first resin adhesive bonding the first conductive connection member to the first electrode in such a manner that the conductive soft layer of the first electrode and the conductive soft layer of the first conductive connection member abut to each other.

2. The solar cell according to claim 1, further comprising:
a second conductive connection member connected with the second electrode for connecting the solar cell to another solar cell, wherein the second conductive connection member includes a conductive soft layer at an area facing the second electrode, and the second electrode includes a conductive soft layer at an area facing the second conductive connection member; and
a second resin adhesive bonding the second conductive connection member to the second electrode in such a manner that the conductive soft layer of the second electrode and the conductive soft layer of the second conductive connection member abut to each other.

3. The solar cell according to claim 1, wherein
the curing temperature of the first resin adhesive is lower than the melting point of the conductive soft layer of the first electrode and the melting point of the conductive soft layer of the first conductive connection member.

4. The solar cell according to claim 2, wherein
the curing temperature of the second resin adhesive is lower than the melting point of the conductive soft layer of the second electrode and the melting point of the conductive soft layer of the second conductive connection member.

5. The solar cell according to claim 1, wherein
the first electrode extends into the conductive soft layer of the first conductive connection member.

6. The solar cell according to claim 1, wherein
the conductive soft layer of the first electrode and the conductive soft layer of the first conductive connection member are in contact with each other with at least one of the conductive soft layer of the first electrode and the conductive soft layer of the first conductive connection member being deformed.

7. The solar cell according to claim 2, wherein
the second electrode extends into the conductive soft layer of the second conductive connection member.

8. The solar cell according to claim 1, wherein
the conductive soft layer of the second electrode and the conductive soft layer of the second conductive connection member are in contact with each other with at least one of the conductive soft layer of the second electrode and the conductive soft layer of the second conductive connection member being deformed.

9. The solar cell according to claim 1, wherein
the first electrode includes first narrow line electrodes parallel to each other with a predetermined distance therebetween, each of the first narrow line electrodes comprising the conductive soft layer of the first electrode.

10. The solar cell according to claim 2, wherein
the second electrode includes second narrow line electrodes parallel to each other with a predetermined distance therebetween, each of the second narrow line electrodes comprising the conductive soft layer of the second electrode.

11. The solar cell according to claim 1, wherein
the first and second resin adhesives are made of hardening resin.

12. The solar cell according to claim 11, wherein
the first and second resin adhesives are made of epoxy-type resin.

13. The solar cell according to claim 1, wherein
the conductive soft layer of the first electrode is softer than the main body of the first electrode.

14. The solar cell according to claim 2, wherein
the conductive soft layer of the second electrode softer than the main body of the second electrode.

15. A solar cell module comprising plural solar cells according to claim 1.

16. A method of manufacturing a solar cell, comprising:
fixing a conductive connection member to an electrode provided on a main surface of a photoelectric body with an adhesive, in such a manner that a conductive soft layer of the electrode and a conductive soft layer of the conductive connection member are in contact with each other and the resin adhesive is provided between the main surface of the photoelectric body and the conductive connection member.

17. A method of manufacturing a solar cell, comprising the steps of:
providing an electrode on a main surface of a photoelectric body, a part of a surface of the electrode comprising a conductive soft layer;
disposing a conductive connection member on the electrode, a part of the a of the conductive connective member comprising a conductive soft layer, the disposing being done in such a manner that the conductive soft layer of the electrode and the conductive soft layer of the conductive connection member are in contact with each other and a resin adhesive is provided between the main surface of the photoelectric body and the conductive connection member; and
heating the resin adhesive so that the conductive connection member is fixed to the electrode on the main surface of the photoelectric body.
